(19) United States
(12) Patent Application Publication
(10) Pub. No.: US 2011/0143287 A1
(43) Pub. Date: Jun. 16, 2011

(54) CATADIOPTRIC SYSTEM, ABERRATION MEASURING APPARATUS, METHOD OF ADJUSTING OPTICAL SYSTEM, EXPOSURE APPARATUS, AND DEVICE MANUFACTURING METHOD

(75) Inventor: Yasuhiro Ohmura, Saitama (JP)

(73) Assignee: Nikon Corporation

(21) Appl. No.: 12/880,017

(22) Filed: Sep. 10, 2010

Related U.S. Application Data
(60) Provisional application No. 61/272,335, filed on Sep. 14, 2009.

(51) Int. Cl. G03F 7/20; G02B 17/08; G03B 27/54; G01B 9/00

(52) U.S. Cl. 430/325; 359/728; 355/67; 356/124

(57) ABSTRACT

According to one embodiment relates to an optical system radially downsized and corrected well for aberration and is applicable, for example, to an aberration measuring apparatus for measuring wavefront aberration of a liquid immersion projection optical system. A catadioptric system of a coaxial type is provided with a first optical system which forms a point optically conjugate with an intersecting point with the optical axis on a first plane intersecting with the optical axis, on a second plane, and a second optical system which guides light from the first optical system to a third plane. The first optical system has a first reflecting surface arranged at or near the first plane, a second reflecting surface having a form of an ellipsoid of revolution the two focuses of which are aligned along the optical axis in a state in which one focus is located at or near a first light transmissive portion, and a medium filling an optical path between the first reflecting surface and the second reflecting surface. The first light transmissive portion is formed in a central region of the first reflecting surface including the optical axis and a second light transmissive portion is formed in a central region of the second reflecting surface including the optical axis. The medium has the refractive index of not less than 1.3. The second optical system has a plurality of lenses.

### CROSS-REFERENCE TO RELATED APPLICATION

This application claims priority to Provisional Application No. 61/272,335 filed on Sep. 14, 2009, by the same Applicant, which is hereby incorporated by reference in its entirety.

### BACKGROUND

1. Field

Respective embodiments of the invention relate to a catadioptric system, aberration measuring apparatus, method of adjusting an optical system, exposure apparatus, and device manufacturing method. More particularly, the present invention relates to a catadioptric system applicable, for example, to an aberration measuring apparatus mounted on an exposure apparatus for manufacturing electronic devices by lithography.

2. Description of the Related Art

Photolithography for manufacture of semiconductor devices and others is carried out using the exposure apparatus which projects and exposes a pattern image of a mask (or reticle) over a photosensitive substrate (a wafer, glass plate, or the like coated with a photoresist) through a projection optical system. In the exposure apparatus, the demand for resolving power (resolution) of the projection optical system is becoming higher and higher with increase in degree of integration of semiconductor devices or the like. For meeting the demand for resolving power of the projection optical system, there is the conventionally known liquid immersion technology to increase the image-side numerical aperture by filling the interior of the optical path between the projection optical system and the photosensitive substrate with a medium like a liquid having a high refractive index.

For achieving high resolution, the projection optical system mounted on the liquid immersion type exposure apparatus (which will also be referred to as “liquid immersion projection optical system”) is required to have extremely small residual aberration. For example, U.S. Patent Publication No. 2006-0170891 proposes a configuration in which an aberration measuring apparatus for measuring wavefront aberration of the liquid immersion projection optical system is mounted on a substrate stage for holding and moving the photosensitive substrate.

### SUMMARY

According to an embodiment of the invention, a catadioptric system of a coaxial type, comprises a first optical system, and a second optical system. The first optical system forms a point optically conjugate with an intersecting point with the optical axis on a first plane intersecting with the optical axis, on a second plane. The second optical system guides light from the first optical system to a third plane. In addition, the first optical system has a first reflecting surface, a second reflecting surface, and a medium. The first reflecting surface is arranged at or near a position of the first plane, and has a first light transmissive portion formed in a central region including the optical axis. The second reflecting surface has a form of an ellipsoid of revolution the two focuses of which are aligned along the optical axis in a state in which one focus is located at or near the first light transmissive portion, and has a second light transmissive portion formed in a central region including the optical axis. The medium fills an optical path between the first reflecting surface and the second reflecting surface, and has a refractive index of not less than 1.3. The second optical system has a plurality of lenses. Light from the intersecting point between the first plane and the optical axis travels through the first light transmissive portion, is successively reflected by the second reflecting surface and the first reflecting surface, and then travels through the second light transmissive portion to enter the second optical system. Furthermore, all reflecting surfaces and all refracting surfaces of the catadioptric system are arranged on an optical axis extending linearly.

For purposes of summarizing the invention, certain aspects, advantages, and novel features of the invention have been described herein. It is to be understood that not necessarily all such advantages may be achieved in accordance with any particular embodiment of the invention. Thus, the invention may be embodied or carried out in a manner that achieves or optimizes one advantage or group of advantages as taught herein without necessarily achieving other advantages as may be taught or suggested herein.

### BRIEF DESCRIPTION OF THE SEVERAL VIEWS OF THE DRAWINGS

A general architecture that implements the various features of the invention will now be described with reference to the drawings. The drawings and the associated descriptions are provided to illustrate embodiments of the invention and not to limit the scope of the invention.

FIG. 1 is an exemplary drawing schematically showing a main configuration of a catadioptric system according to a typical mode;

FIG. 2 is an exemplary drawing schematically showing a configuration of an exposure apparatus according to an embodiment;

FIG. 3 is an exemplary drawing schematically showing a configuration between a boundary lens and a wafer;

FIG. 4 is an exemplary drawing schematically showing an internal configuration of an aberration measuring apparatus according to an embodiment;

FIG. 5 is an exemplary drawing schematically showing a configuration of a catadioptric system according to the first example;

FIG. 6 is an exemplary drawing showing transverse aberration of the catadioptric system according to the first example;

FIG. 7 is an exemplary drawing schematically showing a configuration of a catadioptric system according to the second example;

FIG. 8 is an exemplary drawing showing transverse aberration of the catadioptric system according to the second example;

FIG. 9 is an exemplary drawing schematically showing a configuration of a catadioptric system according to the third example;

FIG. 10 is an exemplary drawing showing transverse aberration of the catadioptric system according to the third example;

FIG. 11 is an exemplary drawing schematically showing a configuration of a catadioptric system according to the fourth example;

FIG. 12 is an exemplary drawing showing transverse aberration of the catadioptric system according to the fourth example;

FIG. 13 is an exemplary flowchart showing manufacturing blocks of semiconductor devices; and

FIG. 14 is an exemplary flowchart showing manufacturing blocks of a liquid crystal device such as a liquid crystal display device.

### DETAILED DESCRIPTION

Various embodiments according to the invention will be described hereinafter with reference to the accompanying drawings.

The basic configuration and operational effect of a catadioptric system according to an embodiment will be described below prior to detailed description of embodiments. The optical system according to the present embodiment is a catadioptric system of a coaxial type in which reflecting and refracting surfaces are arranged on a single optical axis extending linearly. The catadioptric system is advantageous in terms of aberration correction and the coaxial type is advantageous in terms of assembly and optical adjustment of the optical system and, in turn, in terms of manufacture of the optical system.

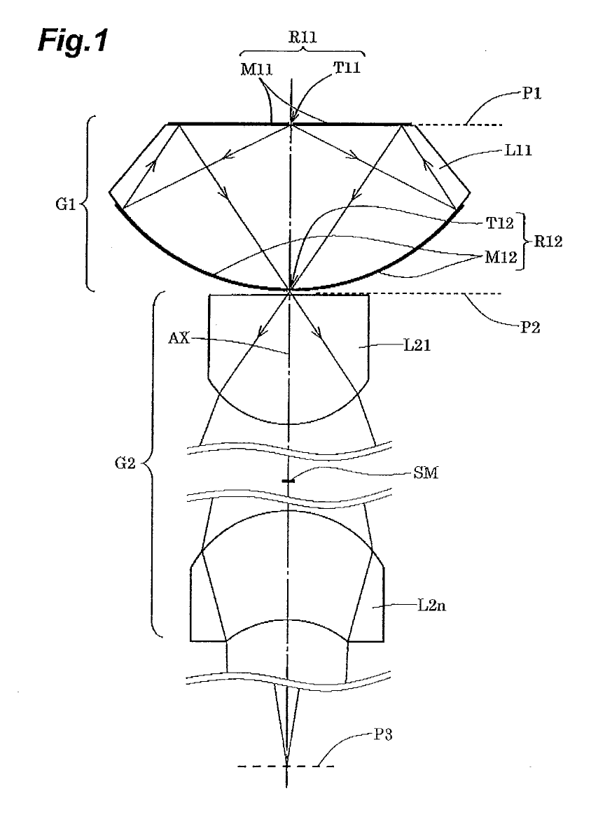

The catadioptric system according to a typical mode of the present embodiment is provided with a first optical system G1 and a second optical system G2 arranged in order along the optical axis AX, as shown in FIG. 1. The first optical system G1 forms a point optically conjugate with an intersecting point with the optical axis AX on a first plane P1 intersecting with the optical axis AX, on a second plane P2. The second optical system G2 guides light from the first optical system G1 to a third plane P3. For example, when the catadioptric system is applied to an aberration measuring apparatus for measuring wavefront aberration of a liquid immersion projection optical system, the first plane P1 corresponds to an image plane of the projection optical system and the third plane P3 to a plane in an optical Fourier transform relation with a wavefront division plane.

The first optical system G1 has a pair of reflecting surfaces R11, R12 opposed to each other along the optical axis AX. The first reflecting surface R11 is arranged at or near the position of the first plane P1. A first light transmissive portion (first light pass portion) T11 is formed in a central region of the first reflecting surface R11 including the optical axis AX. The second reflecting surface R12 has a form of an ellipsoid of revolution the two focuses of which are aligned along the optical axis AX in a state in which one focus is located at or near the position of the first light transmissive portion T11 of the first reflecting surface R11. A second light transmissive portion (second light pass portion) T12 is formed in a central region of the second reflecting surface R12 including the optical axis AX. The shape of the second reflecting surface R12 in the first optical system G1 can be an ellipsoid of revolution without higher-order (second-order and higher) aspherical coefficients. In this case, the shape of the second reflecting surface R12 can be measured by spherical surface measuring technology making use of the two focuses, or can be measured without use of relatively complicated aspherical surface measuring technology using a null element or the like, and is thus advantageous in terms of measurement and formation of the reflecting surface and, in turn, in terms of manufacture of the optical system.

As an example, the reflecting surface R11 can be formed on an optical member (optical block) L11 comprised of an optical material like silica glass and having a form of a planoconvex lens shape with a convex surface on the third plane P3 side. Namely, the reflecting surface R11 is formed by providing a light-blocking reflecting film M11 in a region except for the first light transmissive portion T11 on a plane of the optical member L1 on the first plane P1 side. The reflecting surface R12 is formed by providing a light-blocking reflecting film M12 in a region except for the second light transmissive portion T12 on the ellipsoid of revolution of the optical member L11 on the third plane P3 side.

The light transmissive portions T11, T12 have, for example, a circular shape including the optical axis AX and the size substantially larger than the diffraction limit. As an example, the second reflecting surface R12 can be formed in the ellipsoidal shape. The ellipsoid herein is a spheroid the major axis of which is an axis of revolution, and is also called a prolate or prolate spheroid. When the second reflecting surface R12 is formed in the prolate spheroid shape, the axis of revolution of the prolate spheroid can be made coincident with the optical axis AX.

The first reflecting surface R11 and the second reflecting surface R12 are formed on one common optical member L11 (single optical member without any internal cemented surface corresponding to an interface between optical members). For this reason, the optical path between the first reflecting surface R11 and the second reflecting surface R12 is filled with a medium having the refractive index of not less than 1.3. The second optical system G2 is, for example, a refracting optical system composed of a plurality of lenses. FIG. 1 shows only a first lens L21 disposed nearest to the first optical system G1 and the nth lens L2n disposed nearest to the third plane P3, out of the plurality of lenses constituting the second optical system G2. The first lens L21 is, for example, a positive lens with a convex surface on the third plane P3 side.

In the catadioptric system of the present embodiment, the light from the intersecting point between the first plane P1 and the optical axis AX passes through the first light transmissive portion T11, is then successively reflected by the second reflecting surface R12 and the first reflecting surface R11, and thereafter travels through the second light transmissive portion T12 to enter the second optical system G2. Specifically, the light passing through the first light transmissive portion T11 is reflected on an effective reflection region except for the second light transmissive portion T12 in the second reflecting surface R12 and then impinges on the first reflecting surface R11. The light reflected on an effective reflection region except for the first light transmissive portion T11 in the first reflecting surface R11 passes through the second light transmissive portion T12 to enter the second optical system G2.

In the catadioptric system of the present embodiment, the second reflecting surface R12 is formed in the ellipsoidal shape with the two focuses being aligned along the optical axis AX in the state in which one focus is located at or near the position of the first light transmissive portion T11. For this reason, without need for making the aperture of the second reflecting surface R12 excessively large, the beam taken into the first optical system G1 through the first light transmissive portion T11 can be guided to the second optical system G2, while reducing generation of spherical aberration. Particularly, the first optical system G1 has the magnification of an enlargement ratio from the first plane P1 to the second plane P2. By using the first optical system G1 of this type, it becomes feasible to convert the beam with a large numerical aperture taken thereinto through the first light transmissive portion T11, to a beam with a relatively small numerical aperture and to guide the converted beam to the second optical system G2.

When the second light transmissive portion T12 is located at or near the position of the second plane P2, the light from the intersecting point between the first plane P1 and the optical axis AX travels through the first light transmissive portion T11 and thereafter is focused at or near the position of the second light transmissive portion T12. Namely, this configuration allows the sizes of the light transmissive portions T11, T12 to be kept small. As a result, it is feasible to keep small the center shield portion of the beam the reflection of which is impeded by the light transmissive portions T11, T12 on the reflecting surfaces R11, R12. This means that when the catadioptric system of the present embodiment is applied to the aberration measuring apparatus, it is feasible to keep small a central region where the wavefront aberration cannot be measured on the pupil plane of the projection optical system (in general, an optical system to be examined). When the second optical system G2 is configured as a refracting optical system composed of a plurality of lenses, it is feasible to correct well for coma, curvature of field, etc. occurring in the first optical system G1.

In the catadioptric system of the present embodiment, the optical path between the first reflecting surface R11 and the second reflecting surface R12 is filled with the medium (optical material) having the refractive index of not less than 1.3. For this reason, it becomes feasible, for example, to take a beam with the numerical aperture of not less than 1.3 into the first optical system G1 and, in turn, to apply the catadioptric system to the aberration measuring apparatus for measuring the wavefront aberration of the liquid immersion projection optical system. The medium filling the optical path between the first reflecting surface R11 and the second reflecting surface R12 can also be a liquid (in general, a fluid) having the refractive index of not less than 1.3 at the wavelength of used light, e.g., pure water.

In this way, the present embodiment substantializes the catadioptric system which is applicable, for example, to the aberration measuring apparatus for measuring the wavefront aberration of the liquid immersion projection optical system and which is radially downsized and corrected well for aberration. The aberration measuring apparatus according to the present embodiment is provided with the optical system radially downsized and well corrected for aberration, and is able to measure, for example, the wavefront aberration of the liquid immersion projection optical system. An exposure apparatus according to the present embodiment is able to accurately transfer a pattern onto a photosensitive substrate, for example, through the liquid immersion projection optical system with aberration adjusted using aberration information obtained by the aberration measuring apparatus for measuring the wavefront aberration.

In the catadioptric system of the present embodiment, a positive lens with a convex surface on the third plane P3 side can be used as the first lens L21 disposed nearest to the first optical system G1 in the second optical system G2. This configuration allows the second optical system G2 to be radially downsized and thus substantializes the totally compact form eventually.

In the catadioptric system of the present embodiment, the first reflecting surface R11 and the second reflecting surface R12 are formed on surfaces of one common optical member L11 (single optical member the shape of which is defined by a plurality of faces). This ensures the stability of imaging performance of the optical system. The single optical member, different from an optical structure constructed by cementing a plurality of optical members, is an optical member having no internal cemented surface corresponding to an interface between members. On the other hand, the third example described later illustrates an application of an optical structure constructed by cementing an optical member of a plane-parallel plate shape and an optical member of a planoconvex lens shape, for example, with an adhesive, an optical contact, or the like. In this optical structure, the first reflecting surface R11 is formed on a surface different from a surface cemented to the optical member of the planoconvex lens shape, in the optical member of the plane-parallel plate shape. The second reflecting surface R12 is formed on a surface different from a surface cemented to the optical member of the plane-parallel plate shape, in the optical member of the planoconvex lens shape. The optical structure of this configuration also ensures the stability of imaging performance of the optical system.

In the catadioptric system of the present embodiment, the conic coefficient κ which defines the ellipsoidal surface of the second reflecting surface R12 can satisfy Condition (1) below. When the conic coefficient κ satisfies Condition (1) below, the catadioptric system can be corrected well for spherical aberration. If the conic coefficient is over the upper limit of Condition (1), correction will be insufficient for spherical aberration; if it is below the lower limit, correction will be excessive for spherical aberration. In either case, the correction burden of the spherical aberration increases on the second optical system G2 and the correction itself becomes complicated. When the catadioptric system of the present embodiment is considered to be applied, for example, to the aberration measuring apparatus for measuring the wavefront aberration, a shield portion in a pupil to be measured, or an unmeasurable region will increase if the range of Condition (1) is not met.

−0.20<κ<−0.08 (1)

In the catadioptric system of the present embodiment, the second optical system G2 can be configured as an imaging optical system which forms a point optically conjugate with the intersecting point between the second plane P2 and the optical axis AX, on the third plane P3. In this configuration, when the catadioptric system of the present embodiment is applied to the aberration measuring apparatus, a relay optical system (Fourier transform optical system) is interposed between the catadioptric system and a wavefront division surface.

In the catadioptric system of the present embodiment, a shield member SM (cf. FIG. 1) is arranged in the optical path between the first optical system G1 and the third plane P3. This configuration can prevent the light passing through the second light transmissive portion T12 without being reflected by the second reflecting surface R12 from the intersecting point between the first plane P1 and the optical axis AX, from reaching the third plane P3. When the second optical system G2 is an imaging optical system, the shield member SM can be arranged at or near the position of the pupil of the second optical system G2.

In the catadioptric system of the present embodiment, the second plane P2 is positioned in the optical path of gas between the first optical system G1 and the second optical system G2. In this configuration, even if there is a defect (bubble, foreign matter, or the like) inside the optical member L11, it is feasible to prevent a clear image of the defect from being formed and thus to reduce influence of the defect on the aberration measurement. When it is known that there is almost no defect inside the optical member L11, the first optical system G1 and the second optical system G2 may be cemented to each other, for example, with an adhesive, an optical contact, or the like. In this case, the second plane P2 is positioned in one optical member (corresponding to the optical member L11 or the lens L21 in FIG. 1) out of a pair of optical members cemented to each other. This reduces spherical aberration occurring at the final surface of the first optical system G1 (corresponding to the surface of the second light transmissive portion T12 in FIG. 1) and at the first surface of the second optical system G2 (corresponding to the entrance-side surface of the lens L21 in FIG. 1) and thus simplifies the configuration of the second optical system G2.

The catadioptric system of the present embodiment can be configured to satisfy Condition (2) below. When Condition (2) is satisfied, the center shield portions of the beam in the reflecting surfaces R11, R12 can be kept small. In Condition (2), D is an axial distance between an extension of the first reflecting surface R11 and an extension of the second reflecting surface R12, and L an axial distance between the extension of the first reflecting surface R11 and the second plane P2.

0.95<L/D<1.05 (2)

Specifically, when Condition (2) is satisfied, the first light transmissive portion T11 is limited to the position at or near the first plane P1 and the second light transmissive portion T12 is limited to the position at or near the second plane P2. It allows the center shield portions of the beam in the reflecting surfaces R11, R12 to be kept small. In other words, when Condition (2) is not satisfied, the required sizes of the light transmissive portions T11, T12 become large and it makes the center shield portions of the beam too large. This means that the center region unavailable for the measurement of wavefront aberration becomes too large on the pupil plane of the optical system to be examined, to apply the optical system to the aberration measuring apparatus.

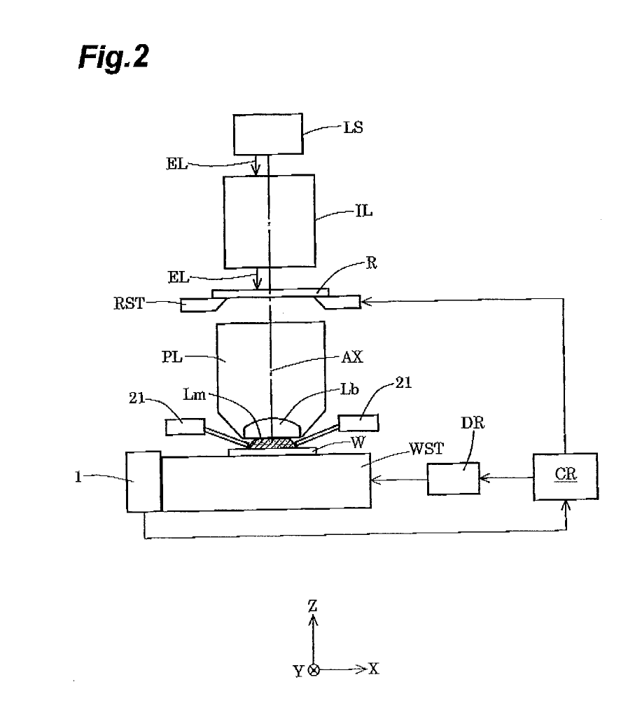

A specific embodiment will be described on the basis of the accompanying drawing. FIG. 2 is an exemplary drawing schematically showing a configuration of an exposure apparatus according to the present embodiment. In FIG. 2, X-axis and Y-axis are set in directions parallel to a transfer surface (exposed surface) of a wafer W as a photosensitive substrate and Z-axis is set in a direction perpendicular to the wafer W. More specifically, the XY plane is set in parallel with a horizontal plane and the +Z-axis is set upward along the vertical direction.

Referring to FIG. 2, exposure light (illumination light) EL is supplied from a light source LS in the exposure apparatus of the present embodiment. The light source LS applicable herein is, for example, an ArF excimer laser light source to supply light at the wavelength of 193 nm. The exposure apparatus of the present embodiment is equipped with an illumination optical system IL comprised of an optical integrator (homogenizer), a field stop, a condenser lens, and so on. The exposure light EL of ultraviolet pulsed light emitted from the light source LS travels through the illumination optical system IL to illuminate a reticle (mask) R.

A pattern to be transferred is formed on the reticle R and a pattern region of a rectangular shape with long sides along the X-direction and short sides along the Y-direction is illuminated. The light passing through the reticle R travels via a liquid immersion projection optical system PL to form a reticle pattern at a projection magnification of a predetermined reduction ratio in an exposure region (shot area) on the wafer (photosensitive substrate) W coated with a photoresist. Namely, the pattern image is formed in the exposure region (or still exposure region) of a rectangular shape with long sides along the X-direction and short sides along the Y-direction on the wafer W, optically corresponding to the illuminated region of the rectangular shape on the reticle R.

The reticle R is held in parallel with the XY plane on a reticle stage RST. A mechanism for moving the reticle R in the X-direction, the Y-direction, and the rotational direction is incorporated in the reticle stage RST. The reticle stage RST is configured so that positions in the X-direction, Y-direction, and rotational direction are measured in real time with reticle laser interferometers (not shown), and controlled based thereon. The wafer W is fixed in parallel with the XY plane on a substrate stage WST through a wafer holder (not shown).

Specifically, the substrate stage WST has a Z-stage (not shown) for moving the wafer W in the Z-direction, and an XY stage (not shown) for moving the Z-stage along the XY plane while holding the Z-stage. The Z-stage controls the focus position (Z-directional position) and inclination angle of the wafer W. The Z-stage is configured so that positions in the X-direction, Y-direction, and rotational direction are measured in real time with wafer laser interferometers (not shown), and controlled based thereon. The XY stage controls the X-direction, Y-direction, and rotational direction of the wafer W.

A main control system CR provided in the exposure apparatus of the present embodiment adjusts the positions of the reticle R in the X-direction, Y-direction, and rotational direction, based on measured values by the reticle laser interferometers. Specifically, the main control system CR transmits a control signal to the mechanism incorporated in the reticle stage RST, to move the reticle stage RST, thereby adjusting the position of the reticle R. Furthermore, the main control system CR adjusts the focus position (Z-directional position) and inclination angle of the wafer W in order to match the surface on the wafer W with the image plane of the projection optical system PL by the autofocus method and auto-leveling method.

Specifically, the main control system CR transmits a control signal to a driving system DR to drive the Z-stage by the driving system DR, thereby adjusting the focus position and inclination angle of the wafer W. Furthermore, the main control system CR adjusts the positions of the wafer W in the X-direction, Y-direction, and rotational direction, based on measured values by the wafer laser interferometers. Specifically, the main control system CR transmits a control signal to the driving system DR to drive the XY stage by the driving system DR, thereby adjusting the positions of the wafer W in the X-direction, Y-direction, and rotational direction.

During exposure, the pattern image of the reticle R is fully projected into a predetermined shot area on the wafer W. Thereafter, the main control system CR transmits a control signal to the driving system DR to drive the XY stage of the substrate stage WST along the XY plane by the driving system DR, thereby implementing block movement of another shot area on the wafer W to the exposure position. In this manner, the block-and-repeat method is carried out to repeat the one-shot exposure operation of the pattern image of the reticle R on the wafer W.

In another method, the main control system CR transmits a control signal to the mechanism incorporated in the reticle stage RST and transmits a control signal to the driving system DR, to drive the reticle stage RST and the XY stage of the substrate stage WST at a speed ratio according to the projection magnification of the projection optical system PL and simultaneously perform scanning exposure of the pattern image of the reticle R in a predetermined shot area on the wafer W. Thereafter, the main control system CR transmits a control signal to the driving system DR to drive the XY stage of the substrate stage WST along the XY plane by the driving system DR, thereby implementing block movement of another shot area on the wafer W to the exposure position.

In this manner, the block-and-scan method is carried out to repeat the scanning exposure operation of the pattern image of the reticle R on the wafer W. Namely, while the positions of the reticle R and the wafer W are controlled by the driving system DR, the wafer laser interferometers, etc., the reticle stage RST and the substrate stage WST and therefore the reticle R and the wafer W are synchronously moved (scanned) along the short-side direction or Y-direction of the rectangular still exposure region and illumination region, whereby scanning exposure of the reticle pattern is implemented in a region having a width equal to the long side of the still exposure region and a length according to a scanning amount (moving amount) of the wafer W, on the wafer W.

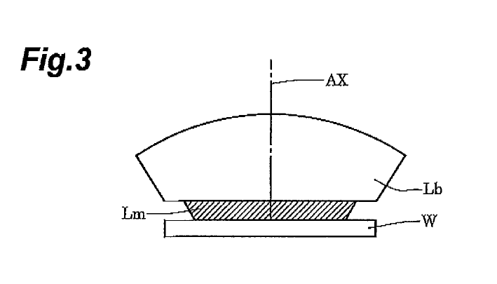

In the present embodiment, as shown in FIG. 3, the optical path between a boundary lens Lb located nearest to the image plane in the projection optical system PL, and the wafer W is filled with a liquid Lm. The boundary lens Lb is a positive lens with a convex surface on the reticle R side and a plane on the wafer W side. In the present embodiment, as shown in FIG. 2, the liquid Lm is circulated in the optical path between the boundary lens Lb and the wafer W, using a supply and drainage system 21. The liquid Lm used herein can be pure water (deionized water) which is readily available in large quantity, for example, in semiconductor manufacturing factories and others.

For continuously filling the interior of the optical path between the boundary lens Lb of the projection optical system PL and the wafer W with the liquid Lm, applicable techniques include, for example, the technology disclosed in International Publication No. WO99/49504, the technology disclosed in Japanese Patent Application Laid-Open No. 10-303114, and so on. In the technology disclosed in International Publication No. WO99/49504, the liquid adjusted at a predetermined temperature is supplied from a liquid supply device through a supply tube and a discharge nozzle so as to fill the optical path between the boundary lens Lb and the wafer W and the liquid is collected from a liquid pool on the wafer W through a collection tube and an inflow nozzle by the liquid supply device.

On the other hand, in the technology disclosed in Japanese Patent Application Laid-Open No. 10-303114, a wafer holder table is constructed in a container shape so as to reserve the liquid, and the wafer W is positioned and held by vacuum contact in a center of an interior bottom (or in the liquid). The apparatus is configured so that the tip of the barrel of the projection optical system PL reaches the interior of the liquid and therefore so that the wafer-side optical surface of the boundary lens Lb reaches the interior of the liquid. As the liquid as an immersion liquid is circulated at a small flow rate in this configuration, it is feasible to prevent deterioration of the liquid by effects of antisepsis, mold prevention, and so on. Furthermore, it is also feasible to prevent aberration variation due to absorption of heat of the exposure light.

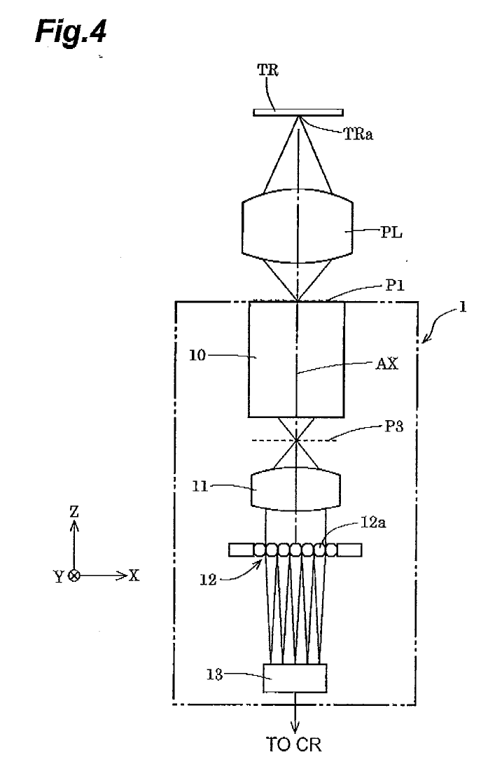

An aberration measuring apparatus 1 for measuring wavefront aberration of the liquid immersion projection optical system PL is mounted on the substrate stage WST. In the aberration measuring apparatus 1, as shown in FIG. 4, a test reticle TR for aberration measurement is placed on the reticle stage RST on the occasion of measuring the wavefront aberration of the projection optical system PL as an optical system to be examined. In the test reticle TR, there are a plurality of circular apertures TRa for aberration measurement two-dimensionally formed (e.g., in a matrix form along the X-direction and Y-direction).

The aberration measuring apparatus 1 is equipped with an objective optical system consisting of a coaxial type catadioptric system 10 and a Fourier transform optical system 11. Namely, the first plane P1 of the catadioptric system 10 according to the present embodiment corresponds to the image plane of the projection optical system PL, and the third plane P3 corresponds to a plane in an optical Fourier transform relation with the entrance plane or a wavefront division plane of a micro fly's eye lens (micro lens array) 12. In the aberration measuring apparatus 1, light emitted through one aperture TRa of the test reticle TR and passing through the projection optical system PL travels via the catadioptric system 10 and Fourier transform optical system 11 to enter the micro fly's eye lens 12.

The micro fly's eye lens 12 is arranged so that its entrance plane (wavefront division plane) is located at or near the position of the exit pupil of the objective optical system (10, 11). The micro fly's eye lens 12 is an optical element constructed, for example, by arraying a large number of microscopic lenses 12a with a cross section of a square shape and with a positive refractive power vertically and horizontally and densely. The micro fly's eye lens 12 is constructed, for example, by forming the microscopic lens group in a plane-parallel plate by etching, and functions as a wavefront dividing element.

A beam entering the micro fly's eye lens 12 is two-dimensionally divided by the large number of microscopic lenses 12a and an image of the aperture TRa is formed near the rear focal plane of each microscopic lens 12a. In other words, a large number of images of the aperture TRa are formed near the rear focal plane of the micro fly's eye lens 12. The large number of images of the aperture TRa formed in this manner are detected by CCD 13 as a two-dimensional imaging device. The output of CCD 13 is supplied to a signal processing unit (not shown) in the main control system CR, for example.

The aberration measuring apparatus 1 is able to measure (or determine) the wavefront aberration of the projection optical system PL about the position of the first light transmissive portion T11, based on the information about the large number of images of the aperture TRa supplied from the CCD 13 to the signal processing unit. Concerning the detailed configuration and action of the aberration measuring apparatus 1 except for the catadioptric system 10, reference can be made, for example, to U.S. Patent Publication No. 2002/0159048 (corresponding to Japanese Patent Application Laid-Open No. 2002-250677) and U.S. Patent Publication No. 2008/0043236 (corresponding to International Publication No. 2006/016584). The teachings of U.S. Patent Publication No. 2002/0159048 (corresponding to Japanese Patent Application Laid-Open No. 2002-250677) and U.S. Patent Publication No. 2008/0043236 (corresponding to International Publication No. 2006/016584) are incorporated herein by reference. The below will describe the configuration and action of each of examples of the catadioptric system 10 according to the embodiment.

In each example, an aspherical surface is represented by Equation (a) below, where y is a height in a direction normal to the optical axis, z a distance (sag) along the optical axis from a tangent plane at a top of the aspherical surface to a position on the aspherical surface at the height y, r a radius of curvature at the top, and κ the conic coefficient (conic constant). In Tables (1), (2), (3), and (4) below, each surface of an aspherical shape is accompanied by mark * to the right of a surface number.

z=(y²/r)/[1+{1−(1+κ)·y²/r²}^{1/2}] (a)

### First Example

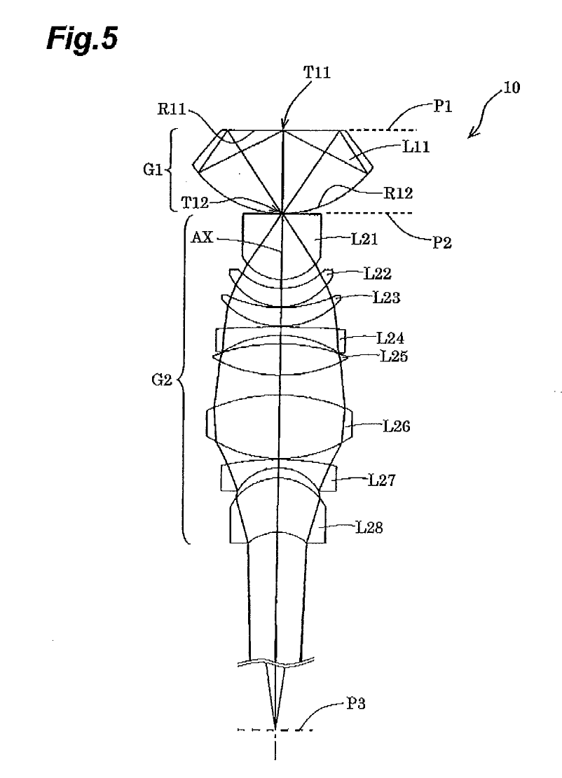

FIG. 5 is an exemplary drawing schematically showing a configuration of the first example of the catadioptric system according to the embodiment. In the catadioptric system 10 according to the first example, the first optical system G1 has the first reflecting surface R11 and the second reflecting surface R12 and these first reflecting surface R11 and second reflecting surface R12 are formed on surfaces of the optical member L11 comprised of silica glass (SiO₂) and having a form of a planoconvex lens shape with a convex surface on the third plane P3 side. Namely, the first reflecting surface R11 is formed on the plane on the first plane P1 side of the optical member L11 and the second reflecting surface R12 is formed on the ellipsoidal surface on the third plane P3 side of the optical member L11. The axis of revolution of the ellipsoidal surface defining the second reflecting surface R12 agrees with the optical axis AX.

The second optical system G2 is composed of, in order from the entrance side of light, a planoconvex lens L21 with a plane on the entrance side (first plane P1 side), a positive meniscus lens L22 with a concave surface on the entrance side, a positive meniscus lens L23 with a concave surface on the entrance side, a negative meniscus lens L24 with a convex surface on the entrance side, a biconvex lens L25, a biconvex lens L26, a negative meniscus lens L27 with a convex surface on the entrance side, and a negative meniscus lens L28 with a convex surface on the entrance side. All the lenses L21 to L28 constituting the second optical system G2 are made of silica glass.

The first light transmissive portion T11 is formed in a circular shape with the radius of 0.02 mm and with the center on the optical axis AX. The second light transmissive portion T12 is formed in a circular shape with the radius of 0.113 mm and with the center on the optical axis AX. The position of the first plane P1, i.e., the position of the image plane of the projection optical system PL as an optical system to be examined is coincident with the position of the first light transmissive portion T11 (or the position of the first reflecting surface R11). The second plane P2 is located in the gas optical path between the second light transmissive portion T12 and the entrance-side plane of the planoconvex lens L21. In the region of the second light transmissive portion T12, the optical member L11 is formed in the ellipsoidal shape. In each example, the refractive index of silica glass for the used wavelength (λ=193.306 nm) is 1.5603261.

Table (1) below provides values of specifications of the catadioptric system 10 according to the first example. In Table (1), NA represents the entrance-side numerical aperture of the catadioptric system 10, β the magnification of an enlargement ratio of the first optical system G1, and Om a maximum object height (the radius of a field region) when the first plane P1 is assumed to be an object plane. In the first example, since the position of the first plane P1 is coincident with the position of the first light transmissive portion T11, the maximum object height Om is equal to the radius of the first light transmissive portion T11. Furthermore, the surface number represents an order of each surface to which the light from the first plane P1 is incident, r a radius of curvature of each surface (mm), d a space of each surface (mm), and n the refractive index for the used wavelength (λ=193.306 nm). The surface space d is assumed to change its sign at every reflection. The notations in Table (1) also apply to Tables (2) to (4) below.

TABLE 1
(MAIN SPECIFICATIONS)
NA = 1.4
β = 40
Om = 0.02 mm
(SPECIFICATIONS OF OPTICAL MEMBERS)

| SURFACE | | | | |
|---|---|---|---|---|
| NUMBER | r | d | n | |
| | ∞ | 10.000000 | 1.5603261 | (P1; T11) |
| 1* | −13.35000 | −10.000000 | 1.5603261 | (R12) |
| 2 | ∞ | 10.000000 | 1.5603261 | (R11) |
| 3* | −13.35000 | 0.100000 | | (T12) |
| 4 | ∞ | 7.864892 | 1.5603261 | (L21) |
| 5 | −5.67845 | 1.088351 | | |
| 6 | −7.42428 | 2.244274 | 1.5603261 | (L22) |
| 7 | −7.21893 | 0.100000 | | |
| 8 | −16.12275 | 2.239416 | 1.5603261 | (L23) |
| 9 | −10.00594 | 0.100000 | | |
| 10 | 122.40073 | 1.000000 | 1.5603261 | (L24) |
| 11 | 13.58740 | 1.030451 | | |
| 12 | 23.87230 | 3.76520 | 1.5603261 | (L25) |
| 13 | −18.09664 | 2.437971 | | |
| 14 | 22.10529 | 7.661335 | 1.5603261 | (L26) |
| 15 | −16.55372 | 0.100211 | | |
| 16 | 32.99440 | 1.000674 | 1.5603261 | (L27) |
| 17 | 5.88987 | 1.284022 | | |
| 18 | 6.78471 | 6.532309 | 1.5603261 | (L28) |
| 19 | 5.84802 | 105.554500 | | |
| | | | | (P3) |

(VALUES CORRESPONDING TO CONDITIONS)

L = 10.04810 mm
D = 10.0 mm
(1) κ = −0.116
(2) L/D = 1.00481

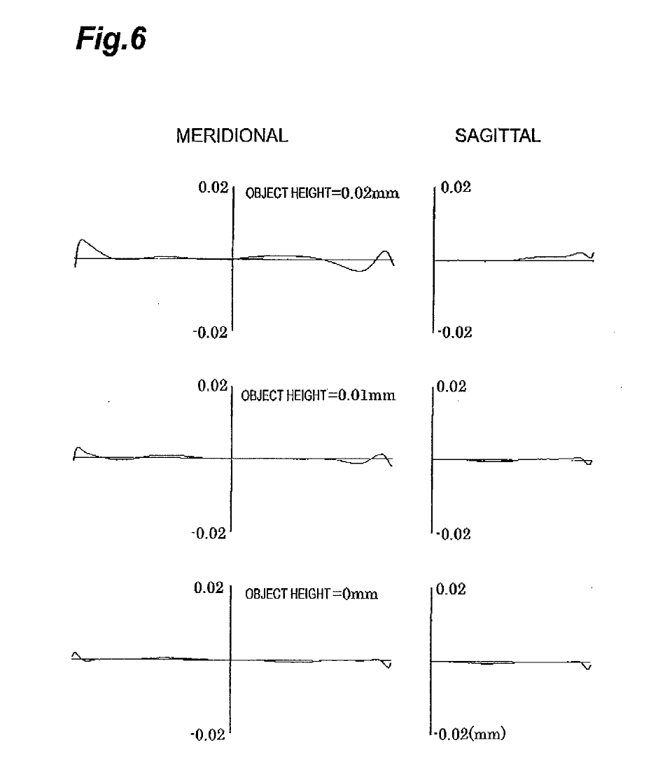

FIG. 6 is an exemplary drawing showing the transverse aberration in the catadioptric system 10 according to the first example. As apparent from the aberration diagrams of FIG. 6, it is seen that in the first example the system is corrected well for aberration though it takes in the beam with the very large numerical aperture (NA=1.4) at the wavelength of 193.306 nm.

### Second Example

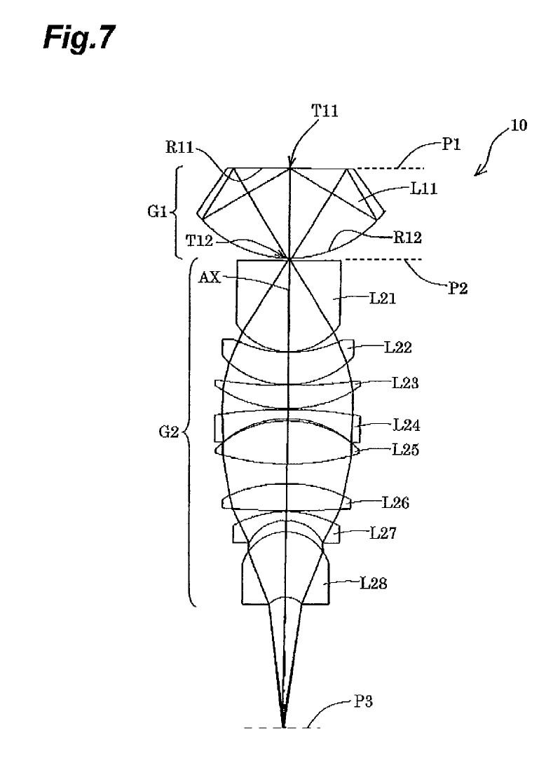

FIG. 7 is an exemplary drawing schematically showing a configuration of the second example of the catadioptric system according to the embodiment. In the catadioptric system 10 according to the second example, the first optical system G1 has the first reflecting surface R11 and the second reflecting surface R12 and these first reflecting surface R11 and second reflecting surface R12 are formed on surfaces of the optical member L11 comprised of silica glass and having a form of a planoconvex lens shape with the convex surface on the third plane P3 side. Specifically, the first reflecting surface R11 is formed on the plane on the first plane P1 side of the optical member L11 and the second reflecting surface R12 is formed on the ellipsoidal surface on the third plane P3 side of the optical member L11. The axis of revolution of the ellipsoidal surface defining the second reflecting surface R12 agrees with the optical axis AX.

The second optical system G2 is composed of, in order from the entrance side of light, a planoconvex lens L21 with a plane on the entrance side (first plane P1 side), a positive meniscus lens L22 with a concave surface on the entrance side, a positive meniscus lens L23 with a concave surface on the entrance side, a negative meniscus lens L24 with a convex surface on the entrance side, a biconvex lens L25, a biconvex lens L26, a negative meniscus lens L27 with a convex surface on the entrance side, and a negative meniscus lens L28 with a convex surface on the entrance side. All the lenses L21 to L28 constituting the second optical system G2 are made of silica glass.

The first light transmissive portion T11 is formed in a circular shape with the radius of 0.02 mm and with the center on the optical axis AX. The second light transmissive portion T12 is formed in a circular shape with the radius of 0.296 mm and with the center on the optical axis AX. The position of the first plane P1, i.e., the position of the image plane of the projection optical system PL as an optical system to be examined is coincident with the position of the first light transmissive portion T11 (or the position of the first reflecting surface R11). The second plane P2 is located in the gas optical path between the second light transmissive portion T12 and the entrance-side plane of the planoconvex lens L21. In the region of the second light transmissive portion T12, the optical member L11 is formed in the ellipsoidal shape. Table (2) below provides values of specifications of the catadioptric system 10 according to the second example. In the second example, as in the first example, the position of the first plane P1 is also coincident with the position of the first light transmissive portion T11 and thus the maximum object height Om is equal to the radius of the first light transmissive portion T11.

TABLE 2
(MAIN SPECIFICATIONS)
NA = 1.35
β = 10
Om = 0.02 mm
(SPECIFICATIONS OF OPTICAL MEMBERS)

| SURFACE | | | | |
|---|---|---|---|---|
| NUMBER | r | d | n | |
| | ∞ | 10.000000 | 1.5603261 | (P1; T11) |
| 1* | −13.40000 | -10.000000 | 1.5603261 | (R12) |
| 2 | ∞ | 10.000000 | 1.5603261 | (R11) |
| 3* | −13.40000 | 0.300000 | | (T12) |
| 4 | ∞ | 10.129470 | 1.5603261 | (L21) |
| 5 | −7.07722 | 0.100000 | | |
| 6 | −13.77373 | 3.585246 | 1.5603261 | (L22) |
| 7 | −10.28167 | 0.100000 | | |
| 8 | −56.53051 | 2.543081 | 1.5603261 | (L23) |
| 9 | −14.74784 | 0.100000 | | |
| 10 | 51.21701 | 1.000000 | 1.5603261 | (L24) |
| 11 | 11.27565 | 0.244843 | | |
| 12 | 11.94743 | 4.816411 | 1.5603261 | (L25) |
| 13 | −28.97152 | 2.185953 | | |
| 14 | 16.07307 | 3.016569 | 1.5603261 | (L26) |
| 15 | −96.84564 | 0.100000 | | |
| 16 | 12.02571 | 1.000000 | 1.5603261 | (L27) |
| 17 | 4.74568 | 1.269210 | | |
| 18 | 5.15353 | 7.233545 | 1.5603261 | (L28) |
| 19 | 2.60433 | 14.348958 | | |
| | | | | (P3) |

(VALUES CORRESPONDING TO CONDITIONS)

L = 10.19067 mm
D = 10.0 mm
(1) κ = −0.125
(2) L/D = 1.019067

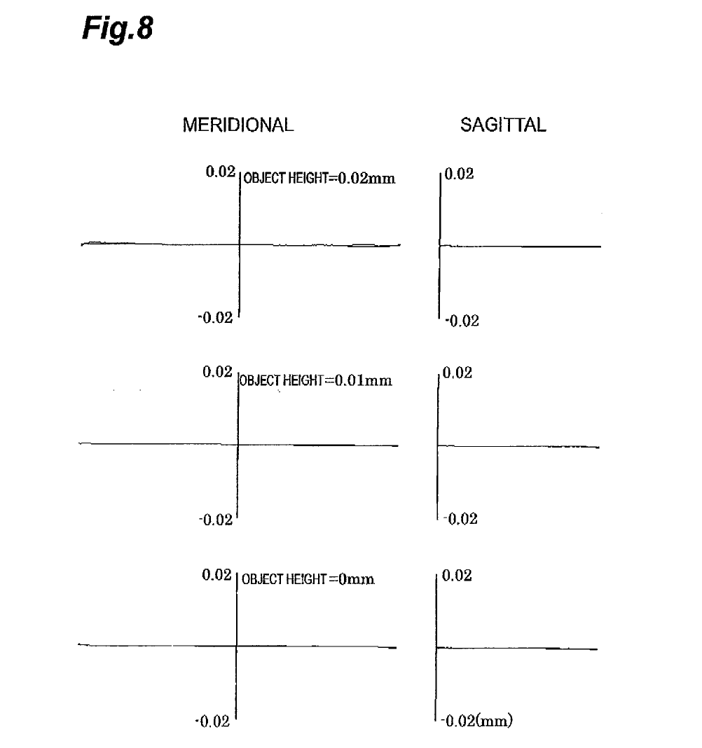

FIG. 8 is an exemplary drawing showing the transverse aberration in the catadioptric system according to the second example. As apparent from the aberration diagrams of FIG. 8, it is seen that in the second example the system is corrected well for aberration though it takes in the beam with the very large numerical aperture (NA=1.35) at the wavelength of 193.306 nm.

### Third Example

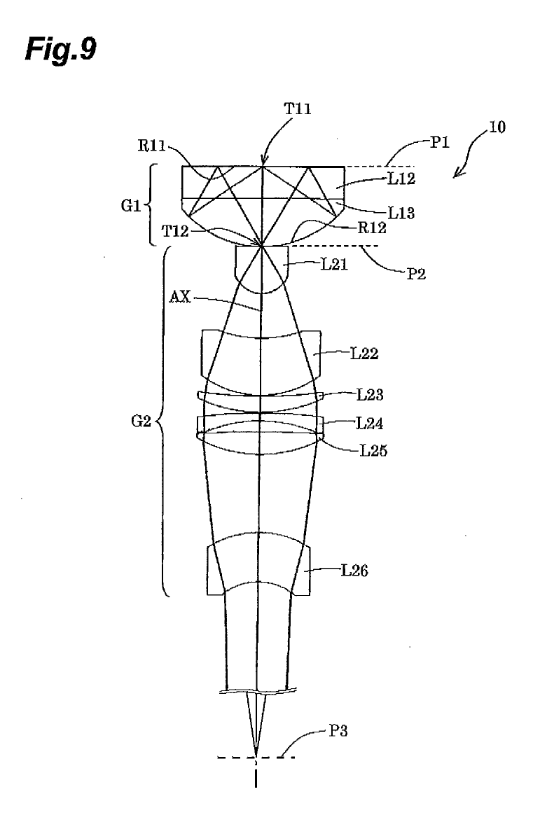

FIG. 9 is an exemplary drawing schematically showing a configuration of the third example of the catadioptric system according to the embodiment. In the catadioptric system 10 according to the third example, the first optical system G1 has the first reflecting surface R11 and the second reflecting surface R12 and these first reflecting surface R11 and second reflecting surface R12 are formed on surfaces of an optical structure constructed by cementing a plurality of optical members. The optical structure is composed of an optical member L12 of a plane-parallel plate shape comprised of silica glass, and an optical member L13 comprised of silica glass and having a form of a planoconvex lens shape with a convex surface on the third plane P3 side, and the plane on the third plane P3 side of the optical member L12 and the plane on the first plane P1 side of the optical member L13 are cemented to each other, for example, with an adhesive, an optical contact, or the like. The first reflecting surface R11 is formed on the plane on the first plane P1 side of the optical member L12 and the second reflecting surface R12 is formed on the ellipsoidal surface on the third plane P3 side of the optical member L13. The axis of revolution of the ellipsoidal surface defining the second reflecting surface R12 agrees with the optical axis AX.

The second optical system G2 is composed of, in order from the entrance side of light, a planoconvex lens L21 with a plane on the entrance side (first plane P1 side), a positive meniscus lens L22 with a concave surface on the entrance side, a positive meniscus lens L23 with a concave surface on the entrance side, a negative meniscus lens L24 with a convex surface on the entrance side, a biconvex lens L25, and a negative meniscus lens L26 with a convex surface on the entrance side. All the lenses L21 to L26 constituting the second optical system G2 are made of silica glass. In the region of the second light transmissive portion T12 the optical member L13 is formed in a planar shape and the plane corresponding to the region of the second light transmissive portion T12 in the optical member L13 and the plane on the first plane P1 side of the planoconvex lens L21 are cemented to each other, for example, with an adhesive, an optical contact, or the like. In other words, the first optical system G1 and the second optical system G2 are cemented to each other.

The first light transmissive portion T11 is formed in a circular shape with the radius of 0.02 mm and with the center on the optical axis AX. The second light transmissive portion T12 is formed in a circular shape with the radius of 0.254 mm and with the center on the optical axis AX. The position of the first plane P1, i.e., the position of the image plane of the projection optical system PL as an optical system to be examined is coincident with the position of the first light transmissive portion T11 (or the position of the first reflecting surface R11). The second plane P2 is located near the second light transmissive portion T12 in the optical member L13. Table (3) below provides values of specifications of the catadioptric system 10 according to the third example.

Virtual surfaces in the specifications of the optical members in Table (3) are cemented surfaces between the optical member L12 and the optical member L13. The value of D in the values corresponding to Conditions in Table (3) is an axial distance between an extension (plane) of the first reflecting surface R11 and an extension (ellipsoidal surface) of the second reflecting surface R12, but is not an axial distance between the extension of the first reflecting surface R11 and the second light transmissive portion T12 of the planar shape. In the third example, as in the first example and the second example, the position of the first plane P1 is also coincident with the position of the first light transmissive portion T11 and thus the maximum object height Om is equal to the radius of the first light transmissive portion T11.

TABLE 3
(MAIN SPECIFICATIONS)
NA = 1.3
β = 40
Om = 0.02 mm
(SPECIFICATIONS OF OPTICAL MEMBERS)

| SURFACE | | | | |
|---|---|---|---|---|
| NUMBER | r | d | n | |
| | ∞ | 4.000000 | 1.5603261 | (P1; T11) |
| 1 | ∞ | 6.000000 | 1.5603261 | (VIRTUAL |
| | | | | SURFACE) |
| 2* | −13.30000 | −6.000000 | 1.5603261 | (R12) |
| 3 | ∞ | −4.000000 | 1.5603261 | (VIRTUAL |
| | | | | SURFACE) |
| 4 | ∞ | 4.000000 | 1.5603261 | (R11) |
| 5 | ∞ | 5.999000 | 1.5603261 | (VIRTUAL |
| | | | | SURFACE) |
| 6 | ∞ | 5.884774 | 1.5603261 | (T12; L21) |
| 7 | −3.58495 | 5.632845 | | |
| 8 | −14.84778 | 7.164699 | 1.5603261 | (L22) |
| 9 | −12.43550 | 0.100000 | | |
| 10 | −59.95655 | 2.010705 | 1.5603261 | (L23) |
| 11 | −18.69997 | 0.100000 | | |
| 12 | 60.95527 | 1.000000 | 1.5603261 | (L24) |
| 13 | 18.10527 | 1.362545 | | |
| 14 | 135.04767 | 2.837707 | 1.5603261 | (L25) |
| 15 | −16.64066 | 9.789441 | | |
| 16 | 12.08485 | 6.151255 | 1.5603261 | (L26) |
| 17 | 7.22350 | 128.701678 | | |
| | | | | (P3) |

(VALUES CORRESPONDING TO CONDITIONS)

L = 9.86394 mm
D = 10.0 mm
(1) κ = −0.105
(2) L/D = 0.986394

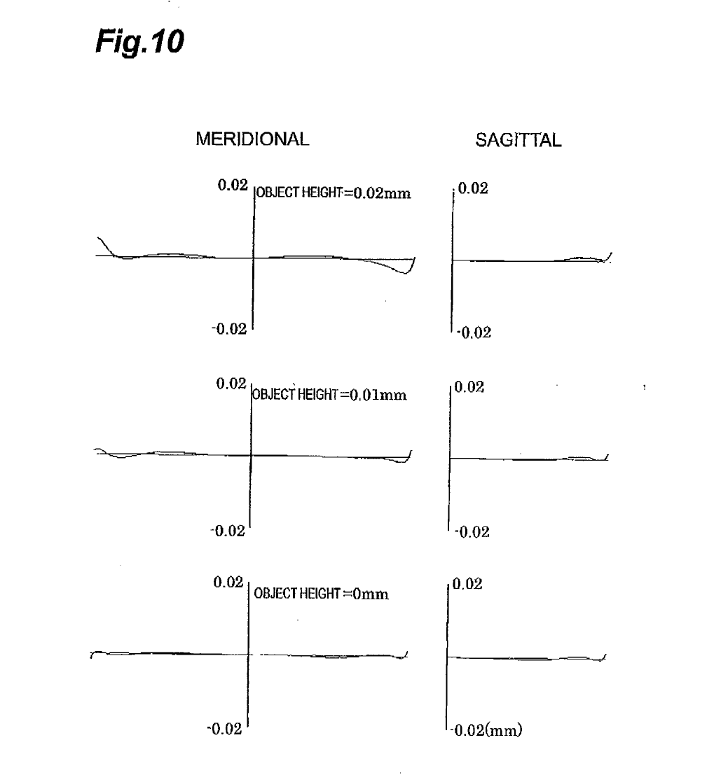

FIG. 10 is an exemplary drawing showing the transverse aberration in the catadioptric system according to the third example. As apparent from the aberration diagrams of FIG. 10, it is seen that in the third example the system is corrected well for aberration though it takes in the beam with the very large numerical aperture (NA=1.3) at the wavelength of 193.306 nm.

### Fourth Example

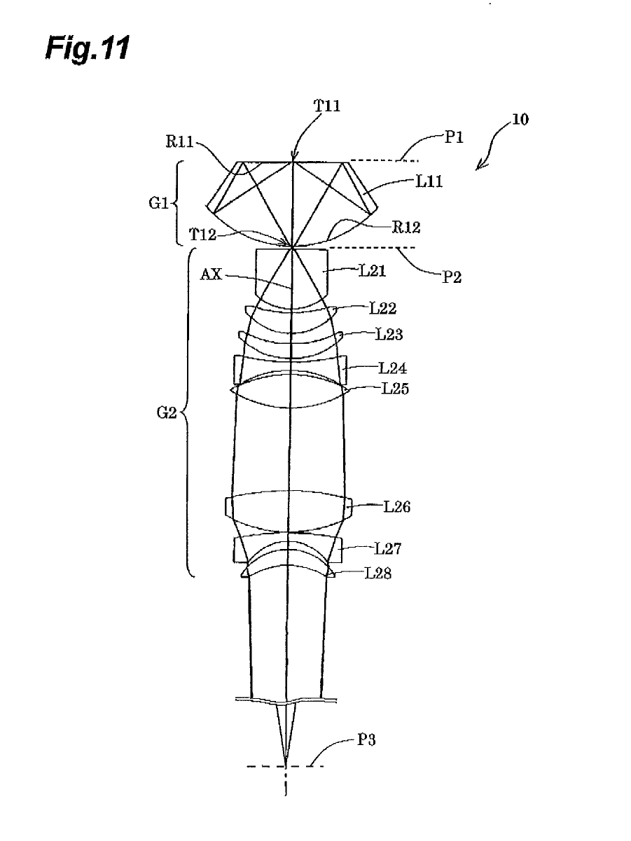

FIG. 11 is an exemplary drawing schematically showing a configuration of the fourth example of the catadioptric system according to the embodiment. In the catadioptric system 10 according to the fourth example, the first optical system G1 has the first reflecting surface R11 and the second reflecting surface R12 and these first reflecting surface R11 and second reflecting surface R12 are formed on surfaces of the optical member L11 comprised of silica glass and having a form of a planoconvex lens shape with a convex surface on the third plane P3 side. Specifically, the first reflecting surface R11 is formed on the plane on the first plane P1 side of the optical member L11 and the second reflecting surface R12 is formed on the ellipsoidal surface on the third plane P3 side of the optical member L11. The axis of revolution of the ellipsoidal surface defining the second reflecting surface R12 agrees with the optical axis AX.

The second optical system G2 is composed of, in order from the entrance side of light, a planoconvex lens L21 with a plane on the entrance side (first plane P1 side), a positive meniscus lens L22 with a concave surface on the entrance side, a positive meniscus lens L23 with a concave surface on the entrance side, a biconcave lens L24, a biconvex lens L25, a biconvex lens L26, a negative meniscus lens L27 with a convex surface on the entrance side, and a positive meniscus lens L28 with a convex surface on the entrance side. All the lenses L21 to L28 constituting the second optical system G2 are made of silica glass.

The first light transmissive portion T11 is formed in a circular shape with the radius of 0.234 mm and with the center on the optical axis AX. The second light transmissive portion T12 is formed in a circular shape with the radius of 0.254 mm and with the center on the optical axis AX. The position of the first plane P1, i.e., the position of the image plane of the projection optical system PL as an optical system to be examined is located 0.1 mm apart from the position of the first light transmissive portion T11 (or the position of the first reflecting surface R11) toward the projection optical system PL. The optical path between the first plane P1 and the first reflecting surface R11 is filled with pure water. The refractive index of pure water for the used wavelength (λ=193.306 nm) is 1.435876.

The second plane P2 is located in the gas optical path between the second light transmissive portion T12 and the entrance-side plane of the planoconvex lens L21. In the region of the second light transmissive portion T12, the optical member L11 is formed in the ellipsoidal shape. Table (4) below provides values of specifications of the catadioptric system 10 according to the fourth example. In the fourth example, unlike the first to third examples, the position of the first plane P1 is not coincident with the position of the first light transmissive portion T11 and therefore the maximum object height Om is not equal to the radius of the first light transmissive portion T11 but is equal to the radius of a field region on the first plane P1 corresponding to the first light transmissive portion T11.

TABLE 4
(MAIN SPECIFICATIONS)
NA = 1.3
β = 40
Om = 0.02 mm
(SPECIFICATIONS OF OPTICAL MEMBERS)

| SURFACE | | | | |
|---|---|---|---|---|
| NUMBER | r | d | n | |
| | ∞ | 0.10000 | 1.435876 | (P1) |
| 1 | ∞ | 10.00000 | 1.5603261 | (T11) |
| 2* | −13.45000 | −10.00000 | 1.5603261 | (R12) |
| 3 | ∞ | 10.00000 | 1.5603261 | (R11) |
| 4* | −13.45000 | 0.40000 | | (T12) |
| 5 | ∞ | 7.01097 | 1.5603261 | (L21) |
| 6 | −6.53351 | 0.45524 | | |
| 7 | −15.76753 | 2.49739 | 1.5603261 | (L22) |
| 8 | −7.15635 | 1.29617 | | |
| 9 | −12.11822 | 1.73998 | 1.5603261 | (L23) |
| 10 | −8.94935 | 0.39960 | | |
| 11 | −25.91075 | 1.00000 | 1.5603261 | (L24) |
| 12 | 11.99403 | 0.49026 | | |
| 13 | 15.18157 | 3.91751 | 1.5603261 | (L25) |
| 14 | −13.86029 | 9.90048 | | |
| 15 | 31.03134 | 4.94399 | 1.5603261 | (L26) |
| 16 | −15.59292 | 0.10000 | | |
| 17 | 35.77250 | 1.00000 | 1.5603261 | (L27) |
| 18 | 5.86511 | 0.96192 | | |
| 19 | 6.78064 | 1.91330 | 1.5603261 | (L28) |
| 20 | 9.07296 | 145.83117 | | |
| | | | | (P3) |

(VALUES CORRESPONDING TO CONDITIONS)

L = 10.05809 mm
D = 10.0 mm
(1) κ = −0.138142
(2) L/D = 1.005809

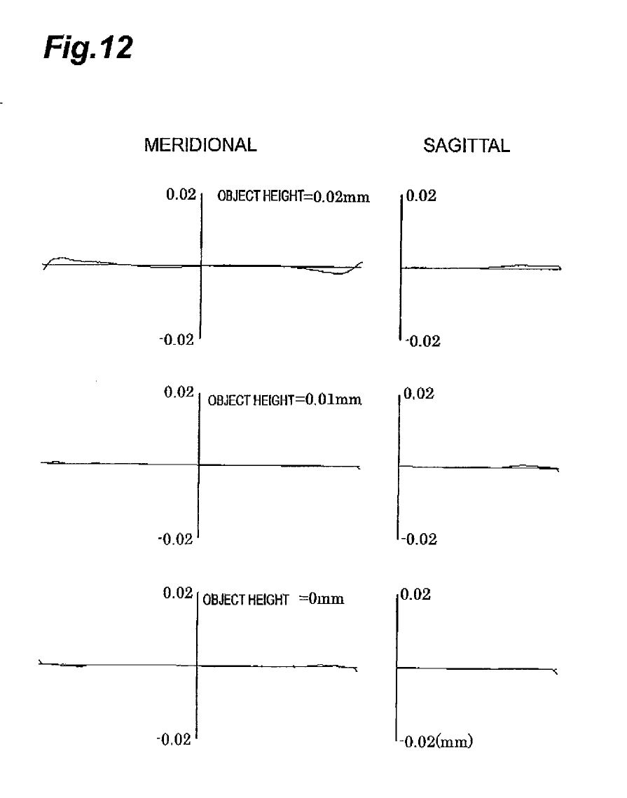

FIG. 12 is an exemplary drawing showing the transverse aberration in the catadioptric system according to the fourth example. As apparent from the aberration diagrams of FIG. 12, it is seen that in the fourth example the system is corrected well for aberration though it takes in the beam with the very large numerical aperture (NA=1.3) at the wavelength of 193.306 nm.

In the aforementioned embodiment, the second optical system G2 is the imaging optical system for keeping the second plane P2 and the third plane P3 in an optically conjugate relation, and the catadioptric system 10 and Fourier transform optical system 11 constitute the objective optical system for the aberration measuring apparatus 1. However, without having to be limited to this, it is also possible to construct the catadioptric system so that the second optical system G2 keeps the second plane P2 and the third plane P3 in an optical Fourier transform relation. In this case, the position of the third plane P3 is coincident with the position of the wavefront division plane (the position of the entrance plane of the micro fly's eye lens 12 in FIG. 4) and installation of the Fourier transform optical system is omitted. In the foregoing embodiment, the second light transmissive portion T12 of the first optical system G1 is located near the second plane P2, but the second transmissive portion T12 may be located at the position of the second plane P2.

In the aforementioned embodiment, the catadioptric system 10 is applied to the aberration measuring apparatus 1 for measuring the aberration of the optical system to be examined (liquid immersion projection optical system PL). However, without having to be limited to this, there are a variety of modes of application of the catadioptric system according to the embodiment. For example, the catadioptric system of the present embodiment can be applied to an objective optical system for a spatial image measuring apparatus for measuring a spatial image of an optical system to be examined. Specifically, the catadioptric system of the present embodiment can be used instead of the relay lens system (275, 276, 277, 278) in the spatial image measuring unit 270 (detecting apparatus) disclosed in FIG. 23 of U.S. Patent Publication No. 2006-0170891.

The catadioptric system of the embodiment is able to form an optical image of a sample by an objective optical system in a state in which a space between the sample and the tip of the objective optical system is immersed in a liquid. Therefore, the catadioptric system can be used as an objective optical system of a detecting apparatus for detecting a defect, foreign matter, or the like on a sample by detecting the optical image with an image sensor. The detecting apparatus of this type can be found with reference, for example, to the disclosure of U.S. Patent Publication No. 2005/0052642). The teachings of U.S. Patent Publication No. 2005/0052642) are incorporated herein by reference. The catadioptric system of the embodiment can also be used as an objective optical system of a microscope for observing an optical image of the sample. Concerning the liquid immersion microscope of this type, reference can be made, for example, to the disclosures of U.S. Pat. No. 7,324,274, U.S. Patent Publication No. 2008/0259446, and U.S. Patent Publication No. 2009/0251691. The teachings of U.S. Pat. No. 7,324,274, U.S. Patent Publication No. 2008/0259446, and U.S. Patent Publication No. 2009/0251691 are incorporated herein by reference.

In the above embodiment, a variable pattern forming device for forming a predetermined pattern on the basis of predetermined electronic data can be used instead of the mask (reticle). The variable pattern forming device applicable herein is, for example, SLM (Spatial Light Modulator) including a plurality of reflective elements driven based on the predetermined electronic data. The exposure apparatus using SLM (Spatial Light Modulator) is disclosed, for example, in Japanese Patent Application Laid-Open No. 2004-304135, U.S. Patent Publication No. 2007/0296936 (corresponding to International Publication No. 2006/080285), and U.S. Pat. No. 7,369,217. Besides the reflective spatial light modulators of the non-emission type, it is also possible to use a transmissive spatial light modulator or an image display device of a self emission type. The catadioptric system of the embodiment can also be used as an objective lens of the liquid immersion exposure apparatus disclosed in U.S. Pat. No. 7,369,217. In this case, SLM for generating the predetermined pattern is disposed on the image plane of the catadioptric system of the embodiment and the photosensitive substrate is disposed on the object plane. The teachings of U.S. Patent Publication No. 2007/0296936 (corresponding to International Publication No. 2006/080285) and U.S. Pat. No. 7,369,217 are incorporated herein by reference.

In the above embodiment the shape of the second reflecting surface R12 of the first optical system G1 may be a shape slightly modified from the ellipsoid of revolution.

The exposure apparatus of the foregoing embodiment is manufactured by assembling various sub-systems containing their respective components as set forth in the scope of claims in the present application, so as to maintain predetermined mechanical accuracy, electrical accuracy, and optical accuracy. For ensuring these various accuracies, the following adjustments are carried out before and after the assembling: adjustment for achieving the optical accuracy for various optical systems; adjustment for achieving the mechanical accuracy for various mechanical systems; adjustment for achieving the electrical accuracy for various electrical systems. The assembling blocks from the various sub-systems into the exposure apparatus include mechanical connections, wire connections of electric circuits, pipe connections of pneumatic circuits, etc. between the various sub-systems. It is needless to mention that there are assembling blocks of the individual sub-systems, before the assembling blocks from the various sub-systems into the exposure apparatus. After completion of the assembling blocks from the various sub-systems into the exposure apparatus, overall adjustment is carried out to ensure various accuracies as the entire exposure apparatus. The manufacture of the exposure apparatus may be carried out in a clean room in which the temperature, cleanliness, etc. are controlled.

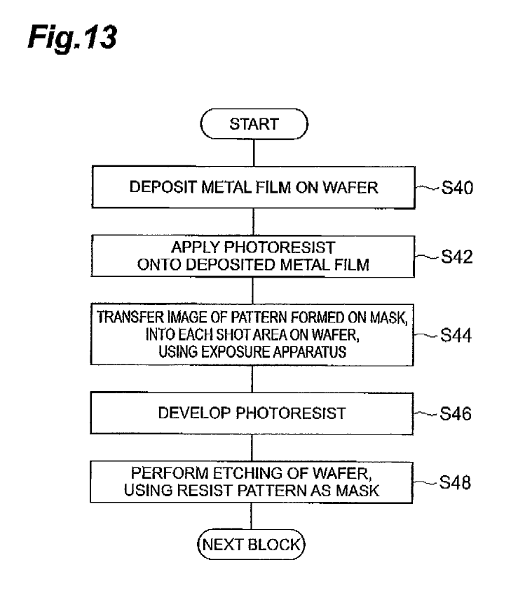

The following will describe a device manufacturing method using the exposure apparatus according to the above-described embodiment. FIG. 13 is an exemplary flowchart showing manufacturing blocks of semiconductor devices. As shown in FIG. 13, the manufacturing blocks of semiconductor devices include depositing a metal film on a wafer W to become a substrate of semiconductor devices (block S40) and applying a photoresist as a photosensitive material onto the deposited metal film (block S42). The subsequent blocks include transferring a pattern formed on a mask (reticle) M, onto each of shot areas on the wafer W, using the exposure apparatus of the above embodiment (block S44: exposure block), and developing the wafer W after completion of the transfer, i.e., developing the photoresist to which the pattern is transferred (block S46: development block).

Thereafter, using the resist pattern made on the surface of the wafer W in block S46, as a mask, processing such as etching is carried out on the surface of the wafer W (block S48: processing block). The resist pattern herein is a photoresist layer in which depressions and projections are formed in a shape corresponding to the pattern transferred by the exposure apparatus of the above embodiment and which the depressions penetrate throughout. Block S48 is to process the surface of the wafer W through this resist pattern. The processing carried out in block S48 includes, for example, at least either etching of the surface of the wafer W or deposition of a metal film or the like.

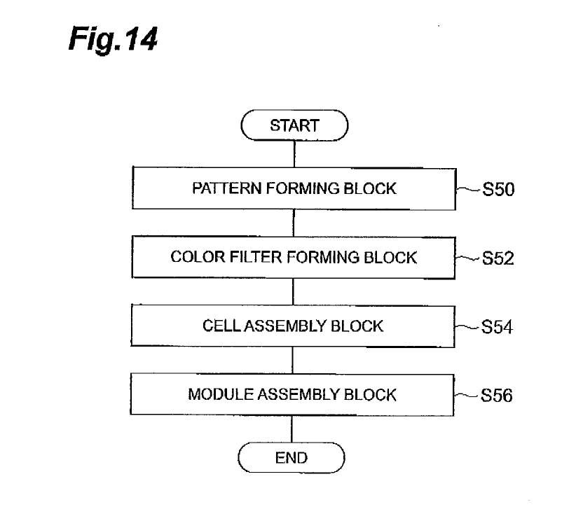

FIG. 14 is an exemplary flowchart showing manufacturing blocks of a liquid crystal device such as a liquid crystal display device. As shown in FIG. 14, the manufacturing blocks of the liquid crystal device include sequentially performing a pattern forming block (block S50), a color filter forming block (block S52), a cell assembly block (block S54), and a module assembly block (block S56). The pattern forming block of block S50 is to form predetermined patterns such as a circuit pattern and an electrode pattern on a glass substrate coated with a photoresist, as a plate P, using the projection exposure apparatus of the above embodiment. This pattern forming block includes: an exposure block of transferring a pattern to a photoresist layer, using the projection exposure apparatus of the above embodiment; a development block of performing development of the plate P to which the pattern is transferred, i.e., development of the photoresist layer on the glass substrate, to form the photoresist layer in the shape corresponding to the pattern; and a processing block of processing the surface of the glass substrate through the developed photoresist layer.

The color filter forming block of block S52 is to form a color filter in which a large number of sets of three dots corresponding to R (Red), G (Green), and B (Blue) are arrayed in a matrix pattern, or in which a plurality of filter sets of three stripes of R, G, and B are arrayed in a horizontal scan direction. The cell assembly block of block S54 is to assemble a liquid crystal panel (liquid crystal cell), using the glass substrate on which the predetermined pattern has been formed in block S50, and the color filter formed in block S52. Specifically, for example, a liquid crystal is poured into between the glass substrate and the color filter to form the liquid crystal panel. The module assembly block of block S56 is to attach various components such as electric circuits and backlights for display operation of this liquid crystal panel, to the liquid crystal panel assembled in block S54.

The embodiment is not limited just to the application to the exposure apparatus for manufacture of semiconductor devices, but can also be widely applied, for example, to the exposure apparatus for display devices such as the liquid crystal display devices formed with rectangular glass plates, or plasma displays, and to the exposure apparatus for manufacture of various devices such as imaging devices (CCDs and others), micro machines, thin film magnetic heads, and DNA chips. Furthermore, the embodiment is also applicable to the exposure block (exposure apparatus) for manufacture of masks (photomasks, reticles, etc.) on which mask patterns of various devices are formed, by the photolithography process.

The above-described embodiment uses the ArF excimer laser light (wavelength: 193 nm) as the exposure light, but, without having to be limited to this, it is also possible to apply the embodiment to any other appropriate laser light source, e.g., a light source to supply KrF excimer laser light (wavelength: 248 nm) or an F₂ laser light source to supply laser light at the wavelength of 157 nm.

In the catadioptric system of the embodiment, since the second reflecting surface is formed in the ellipsoidal shape with one focus at or near the first light transmissive portion, the beam with the large numerical aperture taken into the first optical system can be converted into the beam with the relatively small numerical aperture and the converted beam can be guided to the second optical system while suppressing generation of spherical aberration, without need for making the aperture of the second reflecting surface excessively large. In the catadioptric system of the embodiment, the optical path between the first reflecting surface and the second reflecting surface is filled with the medium having the refractive index of not less than 1.3. For this reason, the catadioptric system is able, for example, to take the beam with the numerical aperture of not less than 1.3 into the first optical system and, in turn, it can be applied to the aberration measuring apparatus for measuring the wavefront aberration of the liquid immersion projection optical system.

In this manner, the embodiment substantializes the catadioptric system that is applicable, for example, to the aberration measuring apparatus for measuring the wavefront aberration of the liquid immersion projection optical system and that is radially downsized and corrected well for aberration. The aberration measuring apparatus according to the embodiment is provided with the optical system radially downsized and corrected well for aberration and thus is able to measure, for example, the wavefront aberration of the liquid immersion projection optical system. The exposure apparatus according to the embodiment is able to accurately transfer the pattern to the photosensitive substrate, for example, through the liquid immersion projection optical system adjusted in wavefront aberration with the use of the aberration measuring apparatus for measuring the wavefront aberration as needed, and therefore to manufacture good devices.

It is apparent that the present invention can be modified in many ways in view of the above description of the present invention. Such modifications should not be construed as a departure from the spirit and scope of the present invention and all improvements obvious to those skilled in the art are intended to be included in the scope of claims which follows.

What is claimed is:

1. A catadioptric system of a coaxial type, comprising:
a first optical system which forms a point optically conjugate with an intersecting point with the optical axis on a first plane intersecting with the optical axis, on a second plane; and
a second optical system which guides light from the first optical system to a third plane,
wherein the first optical system has: a first reflecting surface arranged at or near a position of the first plane, the first reflecting surface having a first light transmissive portion formed in a central region including the optical axis; a second reflecting surface having a form of an ellipsoid of revolution the two focuses of which are aligned along the optical axis in a state in which one focus is located at or near the first light transmissive portion, the second reflecting surface having a second light transmissive portion formed in a central region including the optical axis; and a medium filling an optical path between the first reflecting surface and the second reflecting surface, the medium having a refractive index of not less than 1.3,
wherein the second optical system has a plurality of lenses,
wherein light from the intersecting point between the first plane and the optical axis travels through the first light transmissive portion, is successively reflected by the second reflecting surface and the first reflecting surface, and then travels through the second light transmissive portion to enter the second optical system, and
wherein all reflecting surfaces and all refracting surfaces of the catadioptric system are arranged on an optical axis extending linearly.

2. The catadioptric system according to claim 1, wherein the second optical system has a first lens disposed nearest to the first optical system, with a convex surface on the third plane side.

3. The catadioptric system according to claim 2, wherein the first lens has a positive refractive power.

4. The catadioptric system according to claim 1, wherein the first optical system has an enlargement magnification ratio from the first plane toward the second plane.

5. The catadioptric system according to claim 1, wherein the first reflecting surface is formed in a planar shape and the second reflecting surface is formed in a prolate spheroid shape.

6. The catadioptric system according to claim 5, wherein an axis of revolution of the prolate spheroid agrees with the optical axis.

7. The catadioptric system according to claim 1, wherein the second light transmissive portion is arranged at or near a position of the second plane.

8. The catadioptric system according to claim 1, comprising:
a single optical member a shape of which is defined by a plurality of faces,
wherein the first reflecting surface is formed on one face of the single optical member and wherein the second reflecting surface is formed on another face of the single optical member.

9. The catadioptric system according to claim 1, comprising:
an optical structure comprised of a first member and a second member a shape of each of which is defined by a plurality of faces and which are cemented to each other,
wherein the first reflecting surface is formed on a face different from a face cemented to the second member out of the plurality of faces of the first member and wherein the second reflecting surface is formed on a face different from a face cemented to the first member out of the plurality of faces of the second member.

10. The catadioptric system according to claim 1, wherein the conic coefficient κ defining the ellipsoid of revolution of the second reflecting surface satisfies the following condition:
−0.20<κ<−0.08.

11. The catadioptric system according to claim 1, wherein the second optical system includes a refracting optical system.

12. The catadioptric system according to claim 1, wherein the second optical system includes an imaging optical system which forms a point optically conjugate with an intersecting point between the second plane and the optical axis, on the third plane.

13. The catadioptric system according to claim 1, further comprising:
a shield member for preventing the light from the intersecting point between the first plane and the optical axis from reaching the third plane through the second light transmissive portion without being reflected by the second reflecting surface.

14. The catadioptric system according to claim 13, wherein the shield member is arranged in an optical path between the first optical system and the third plane.

15. The catadioptric system according to claim 13, wherein the second optical system includes an imaging optical system which forms a point optically conjugate with an intersecting point between the second plane and the optical axis, on the third plane, and
wherein the shield member is arranged at or near a position of a pupil of the second optical system.

16. The catadioptric system according to claim 1, wherein the second plane is located in a gas optical path between the first optical system and the second optical system.

17. The catadioptric system according to claim 1, wherein an optical member forming at least a part of the first optical system and an optical member forming at least a part of the second optical system are cemented to each other, and
wherein the second plane is located in one optical member out of the pair of optical members cemented to each other.

18. The catadioptric system according to claim 1, wherein the catadioptric system satisfies the following condition:
0.95<L/D<1.05,
where D is a distance along the optical axis between an extension of the first reflecting surface and an extension of the second reflecting surface and L a distance along the optical axis between the extension of the first reflecting surface and the second plane.

19. An aberration measuring apparatus configured to measure aberration of an optical system to be examined, comprising:
the catadioptric system according to claim 1.

20. The aberration measuring apparatus according to claim 19, wherein the catadioptric system is arranged so that the first plane coincides with an image plane of the optical system to be examined.

21. A method of adjusting an optical system, comprising: using aberration information obtained by the aberration measuring apparatus according to claim 19, to adjust the optical system to be examined.

22. An exposure apparatus which exposes a predetermined pattern located at or near an object plane of an optical system to be examined, over a photosensitive substrate located at or near an image plane of the optical system to be examined, comprising:
the aberration measuring apparatus according to claim 19.

23. An exposure apparatus comprising the optical system to be examined, which was adjusted by the adjusting method according to claim 21, the exposure apparatus configured to expose a predetermined pattern located at or near an object plane of the adjusted optical system to be examined, over a photosensitive substrate located at or near an image plane of the optical system to be examined.

24. An exposure apparatus, comprising:
the catadioptric system according to claim 1, and
the exposure apparatus exposing a predetermined pattern over a photosensitive substrate by means of the catadioptric system.

25. A device manufacturing method, comprising:
exposing the predetermined pattern over the photosensitive substrate, using the exposure apparatus according to claim 22;
developing the photosensitive substrate to which the predetermined pattern is transferred, thereby to form a mask layer in a shape corresponding to the predetermined pattern, on a surface of the photosensitive substrate; and
processing the surface of the photosensitive substrate through the mask layer.

26. A device manufacturing method, comprising:
exposing the predetermined pattern over the photosensitive substrate, using the exposure apparatus according to claim 24;
developing the photosensitive substrate to which the predetermined pattern is transferred, thereby to form a mask layer in a shape corresponding to the predetermined pattern, on a surface of the photosensitive substrate; and
processing the surface of the photosensitive substrate through the mask layer.

27. An inspection apparatus which inspects a sample, comprising the catadioptric system according to claim 1, wherein light having traveled via the sample arranged on the first plane, is guided to the catadioptric system.
